(19) United States
(12) Patent Application Publication
(10) Pub. No.: US 2010/0211203 A1
(43) Pub. Date: Aug. 19, 2010

(54) SUBSTRATE PROCESSING SYSTEM AND SUBSTRATE TRANSFER METHOD

(75) Inventors: Hiroki OKA, Nirasaki City (JP); Hiroshi NARUSHIMA, Nirasaki City (JP)

Correspondence Address: CANTOR COLBURN, LLP, 20 Church Street, 22nd Floor, Hartford, CT, 06103, US

(73) Assignee: TOKYO ELECTRON LIMITED, Tokyo (JP)

(21) Appl. No.: 12/705,192

(22) Filed: Feb. 12, 2010

(30) Foreign Application Priority Data
Feb. 17, 2009 (JP) 2009-33776

(51) Int. Cl. H01L 21/68; G06F 7/00; H01L 21/677; G06F 19/00

(52) U.S. Cl. 700/103; 700/229; 700/97

(57) ABSTRACT

The substrate processing system includes a controller that transfers the substrate by using a transfer apparatus or controls processing of the substrate in a processing apparatus. A recipe setter of the controller sets a processing recipe. A memory stores an initial reference location of a transfer arm, a first correlation between the processing recipe and a sidewall temperature of a processing chamber, and a second correlation between the sidewall temperature of the processing chamber and a compensated value of a reference location. A compensator compensates a reference location of the transfer arm based on the processing recipe set in the recipe setter and the initial reference location, the first correlation, and the second correlation stored in the memory.

### CROSS-REFERENCE TO RELATED PATENT APPLICATIONS

This application claims the benefit of Japanese Patent Application No. 2009-033776, filed on Feb. 17, 2009, in the Japan Patent Office, the disclosure of which is incorporated herein in its entirety by reference.

### BACKGROUND OF THE INVENTION

1. Field of the Invention

The present invention relates to a substrate processing system for performing a predetermined process on a substrate by using a predetermined recipe, and a substrate transfer method performed in the substrate processing system.

2. Description of the Related Art

While manufacturing a semiconductor device or a liquid crystal display device, various processes, such as an etching process, an ashing process, and a film forming process, are performed on a substrate. When such processes are performed, a so-called multi-chamber type substrate processing system is used, in which a plurality of processing apparatuses are disposed around a main transfer chamber, in order to obtain consistency, connectivity, or combination of the processes.

According to the substrate processing system, a substrate to be processed is carried into a processing chamber of each processing apparatus while a processed substrate is carried out of each processing chamber, by a transfer arm of a transfer apparatus formed in the main transfer chamber. Also, a load lock chamber is connected to the main transfer chamber, and thus when a substrate is carried to and from the outside environment, the processing chamber and the main transfer chamber process a plurality of substrates while maintaining vacuum states.

Also, according to the substrate processing system, when a substrate is carried into the processing chamber, the substrate is transferred above a loading stage inside the processing chamber by using the transfer arm of the transfer apparatus, the substrate is loaded onto an elevation pin by protruding the elevation pin from the loading stage, and then the transfer arm is withdrawn into the main transfer chamber. Next, the elevation pin is lowered so as to load the substrate on the loading stage. When the substrate is carried out of the processing chamber, the substrate on the loading stage is elevated/lowered by the elevation pin and then is delivered to the transfer arm. Also, while transferring the substrate by using the transfer apparatus, an operation known as teaching for setting an accurate location of the transfer arm is performed initially, in order to accurately transfer the substrate to a predetermined location of the loading stage. The teaching is performed by an operator, generally at normal temperature.

However, the processing of the substrate in the processing apparatus is generally performed by adjusting a temperature in the processing chamber to be higher than normal temperature. Moreover, recently, the required atmosphere temperature is gradually increasing. As such, when the atmosphere temperature of the processing chamber is adjusted to be relatively high, the processing chamber thermally expands compared to when the teaching is performed at normal temperature, and thus the location of the loading stage in the processing chamber changes. In this case, even when the location of the transfer arm is set during the teaching, the substrate cannot be accurately transferred to the predetermined location of the loading stage. Such deviation of the substrate with respect to the loading stage cannot be ignored in view of the recent tendency towards larger-sized substrates and the minuteness of products.

Accordingly, Patent Document 1 suggests forming, in a substrate processing apparatus (substrate processing system), a temperature sensor for detecting a temperature of a processing chamber, and accordingly compensating a reference location in the processing chamber of a transfer apparatus body according to a displacement of the processing chamber corresponding to a temperature detected by the temperature sensor at a predetermined timing, and controlling transferring of a substrate of the transfer apparatus body based on the compensated reference location, while transferring the substrate with respect to a loading stage in the processing chamber by using the transfer apparatus. Also, when the processing chamber is thermally expanded, the reference location is automatically compensated so that the substrate is transferred to a predetermined location in the processing chamber by using the transfer apparatus.

### PRIOR ART

[Patent Document 1] Japanese Laid-Open Patent Publication No. 2008-147483

However, when the substrate processing system described in the Patent Document 1 is used, a plurality of temperature sensors need to be installed in order to accurately detect a temperature of an outer wall of the processing chamber, or installed as a countermeasure for defect. In this case, not only do costs increase due to the necessity of the temperature sensors, but also the wirings become complicated, and thus cost for manufacturing and processing the processing chamber increase.

In addition, since a temperature sensor needs to be formed in each of the processing chambers, a structure of the substrate processing system becomes complicated.

### SUMMARY OF THE INVENTION

To solve the above and/or other problems, the present invention provides a substrate processing system having a simplified structure, in which a substrate is quickly and highly precisely transferred to a predetermined location with respect to a loading stage in a processing chamber.

According to an aspect of the present invention, a substrate processing system includes: a processing chamber for accommodating a loading stage for accommodating a substrate and including an opening for carrying the substrate into and out of the processing chamber; a processing mechanism for performing a predetermined process on a substrate disposed on the loading stage, based on a predetermined processing recipe; a transfer arm for transferring the substrate with respect to the loading stage through the opening; a controller for controlling the transfer of the substrate by the transfer arm, wherein the controller includes: a memory for storing an initial reference location predetermined before processing the substrate as a reference location of the transfer arm that is set in such a way that the substrate is disposed at a predetermined location with respect to the loading stage, and a relationship between the processing recipe and a compensated value of the reference location when the substrate is processed; and a compensator for compensating the reference location when the substrate is processed, based on the processing recipe, the initial reference location, and the relationship.

According to the present invention, since the initial reference location and the relationship are stored in the memory, when the processing recipe is set, the compensator may compensate the reference location of the transfer arm when the substrate is processed. In other words, the location of the transfer arm may be compensated according to the processing recipe in such a way that the substrate is disposed at a predetermined location with respect to the loading stage. Accordingly, even when the processing chamber thermally expands as the temperature in the processing chamber increases, the transfer arm may be moved based on the reference location compensated by the compensator, and thus the substrate may be highly precisely transferred to the predetermined location with respect to the loading stage by the transfer arm. In this case, since the reference location is not required to be manually compensated unlike a conventional technology, the reference location may be accurately compensated without an error. Moreover, since a temperature sensor for detecting a temperature of the processing chamber is not required unlike a conventional technology, a structure of the substrate processing system may be simplified.

The controller may further include a recipe setter for controlling the process of the substrate by the processing mechanism and setting the processing recipe, wherein, when the processing recipe is updated in the recipe setter, the compensated reference location in the compensator may be updated.

The relationship may include a first correlation between the processing recipe and a sidewall temperature of the processing chamber, and a second correlation between the sidewall temperature of the processing chamber and the compensated value of the reference location.

A plurality of each of the initial reference location, the first correlation, and the second correlation may be stored in the memory according to a characteristic of the processing chamber. Here, the characteristic of the processing chamber may be a material, a structure, or a size of the processing chamber.

The initial reference location may be set under an atmosphere of normal temperature. Here, normal temperature may be between 20° C. and 40° C.

The reference location may be set based on a distance of a length direction of the transfer arm.

The reference location may be a location where the transfer arm delivers the substrate with respect to the loading stage.

According to another aspect of the present invention, a substrate transfer method is provided in which a substrate is transferred by a transfer arm with respect to a loading stage in a processing chamber where a predetermined process is performed on the substrate based on a predetermined processing recipe. The substrate transfer method includes: setting an initial reference location before processing the substrate, as a reference location of the transfer arm that is set in such a way that the substrate is disposed at a predetermined location with respect to the loading stage; obtaining a relationship between the processing recipe and a compensated value of the reference location when the substrate is processed; compensating the reference location when the substrate is processed, based on the processing recipe, the initial reference location, and the relationship; and transferring the substrate with respect to the loading stage by the transfer arm, based on the compensated reference location.

The compensating of the reference location may be performed whenever the processing recipe is updated.

The relationship may include a first correlation between the processing recipe and a sidewall temperature of the processing chamber, and a second correlation between the sidewall temperature of the processing chamber and the compensated value of the reference location, and the compensating of the reference location may be performed based on the processing recipe, the initial reference location, the first correlation, and the second correlation.

A plurality of each of the initial reference location, the first correlation, and the second correlation may be obtained according to a characteristic of the processing chamber.

The setting of the initial reference location may be performed under an atmosphere of normal temperature.

The reference location may be set based on a distance of a length direction of the transfer arm.

The reference location may be a location where the transfer arm delivers the substrate with respect to the loading stage.

### BRIEF DESCRIPTION OF THE DRAWINGS

The above and other features and advantages of the present invention will become more apparent by describing in detail exemplary embodiments thereof with reference to the attached drawings in which:

FIG. 1 is a plan view schematically illustrating a structure of a substrate processing system, according to an embodiment of the present invention;

FIG. 2 is a longitudinal cross-sectional view schematically illustrating a structure of a transfer apparatus;

FIG. 3 is a longitudinal cross-sectional view schematically illustrating a structure of a processing apparatus;

FIG. 4 is a block diagram illustrating a structure of a controller;

FIG. 5 is a diagram illustrating how a substrate is transferred by transfer arm, when a processing chamber is thermally expanded;

FIG. 6 is a graph showing a second correlation between a sidewall temperature of a processing chamber and a compensated value of a reference location; and

FIG. 7 is a flowchart illustrating a process performed in a substrate processing system.

### DETAILED DESCRIPTION OF THE INVENTION

The attached drawings for illustrating exemplary embodiments of the present invention are referred to in order to gain a sufficient understanding of the present invention, the merits thereof, and the objectives accomplished by the implementation of the present invention. Hereinafter, the present invention will be described in detail by explaining exemplary embodiments of the invention with reference to the attached drawings. Like reference numerals in the drawings denote like elements.

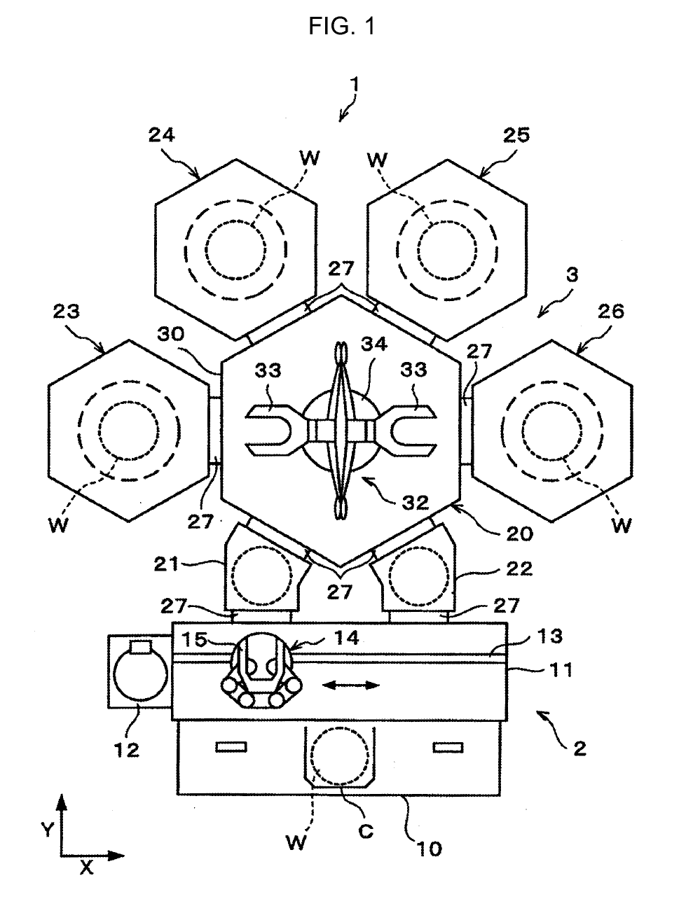

FIG. 1 is a plan view schematically illustrating a structure of a substrate processing system 1 according to an embodiment of the present invention. A substrate W according to the present embodiment may be a semiconductor wafer.

Referring to FIG. 1, the substrate processing system 1 has a structure in which a cassette station 2, to and from which a plurality of substrates W are carried in and out in a cassette unit, and a processing station 3, which includes a plurality of processing apparatuses that process the substrates W one-by-one, are integrally connected to each other.

The cassette station 2 includes a cassette loading unit 10, a transfer chamber 11, and an alignment unit 12 for determining locations of substrate W. A plurality of cassettes C, for example, three cassettes C that can accommodate the plurality of substrates W may be disposed on the cassette loading unit 10 in parallel along an X direction (right and left direction of FIG. 1). The transfer chamber 11 is disposed adjacent to the cassette loading unit 10 in a positive Y direction (upper portion in FIG. 1). A transfer rail 13 extending in the X direction, and a substrate transfer unit 14 moving on the transfer rail 13 are disposed in the transfer chamber 11. The alignment unit 12 is disposed adjacent to the transfer chamber 11 in a negative X direction (left direction of FIG. 1). The substrate transfer unit 14 in the transfer chamber 11 includes a multi-jointed arm 15 that freely rotates, expands, and contracts, and thus may transfer the substrates W with respect to the cassette C of the cassette loading unit 10, the alignment unit 12, and load lock chambers 21 and 22 of the processing station 3 that will be described later.

A main transfer chamber 20, which may depressurize the inner space thereof, is formed in the center of the processing station 3. The main transfer chamber 20, for example, has roughly a hexagon shape when viewed from above, and the load lock chambers 21 and 22 and, for example, four processing apparatuses 23 through 26 are connected around the main transfer chamber 20.

The load lock chambers 21 and 22 are disposed between the main transfer chamber 20 and the transfer chamber 11 of the cassette station 2, thereby connecting the main transfer chamber 20 and the transfer chamber 11. The load lock chambers 21 and 22 include a loading unit (not shown) of the substrate W, and may maintain the inner spaces of the load lock chambers 21 and 22 in a depressurized state.

Gate valves 27, which tightly seal spaces between the transfer chamber 11 and each of the load lock chambers 21 and 22, between the main transfer chamber 20 and each of the load lock chambers 21 and 22, and between the main transfer chamber 20 and each of the processing apparatuses 23 through 26, and are configured to close and open, are each formed between the transfer chamber 11 and each of the load lock chambers 21 and 22, between the main transfer chamber 20 and each of the load lock chambers 21 and 22, and between the main transfer chamber 20 and each of the processing apparatuses 23 through 26, respectively.

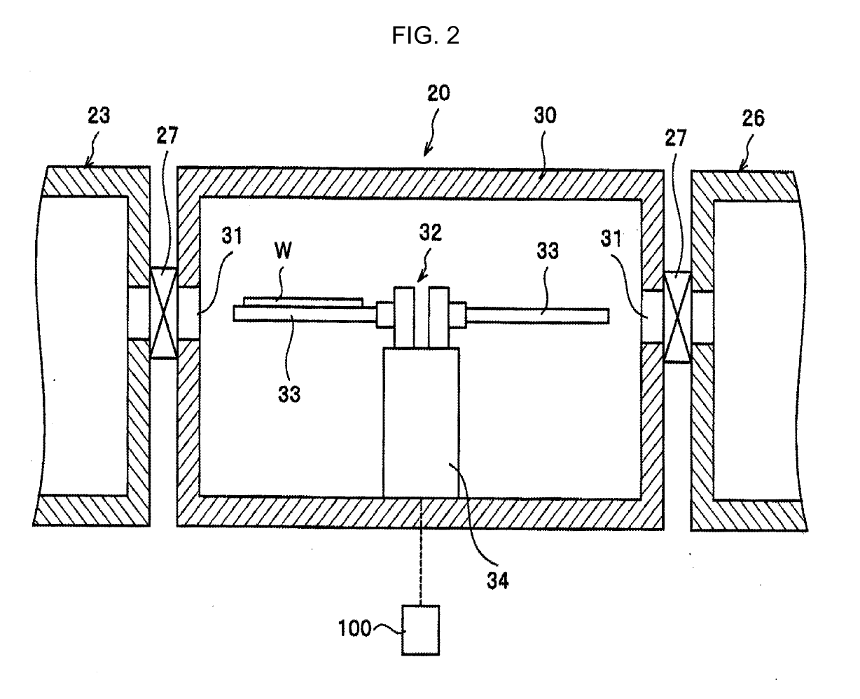

The main transfer chamber 20 includes a transfer chamber 30 that is sealable, as shown in FIG. 2. Openings 31 for carrying the substrates W into and out of the transfer chamber 30 are each formed on sides of the transfer chamber 30 respectively, at locations corresponding to the gate valves 27. Also, a transfer apparatus 32 is disposed inside the transfer chamber 30. The transfer apparatus 32 may include two transfer arms 33, and an arm holding member 34 for holding each of the transfer arms 33. Each transfer arm 33 is configured to freely rotate, expand, and contract, and thus may transfer the substrates W with respect to the load lock chambers 21 and 22 and the processing apparatuses 23 through 26 around the main transfer chamber 20. The transferring of the substrates W by the transfer apparatus 32 is controlled by a controller 100 that will be described later.

The processing apparatuses 23 through 26 are plasma processing apparatuses for processing a predetermined process, such as a plasma process, based on a predetermined processing recipe. In the present embodiment, a chemical vapor deposition (CVD) process is described as an example of the plasma process.

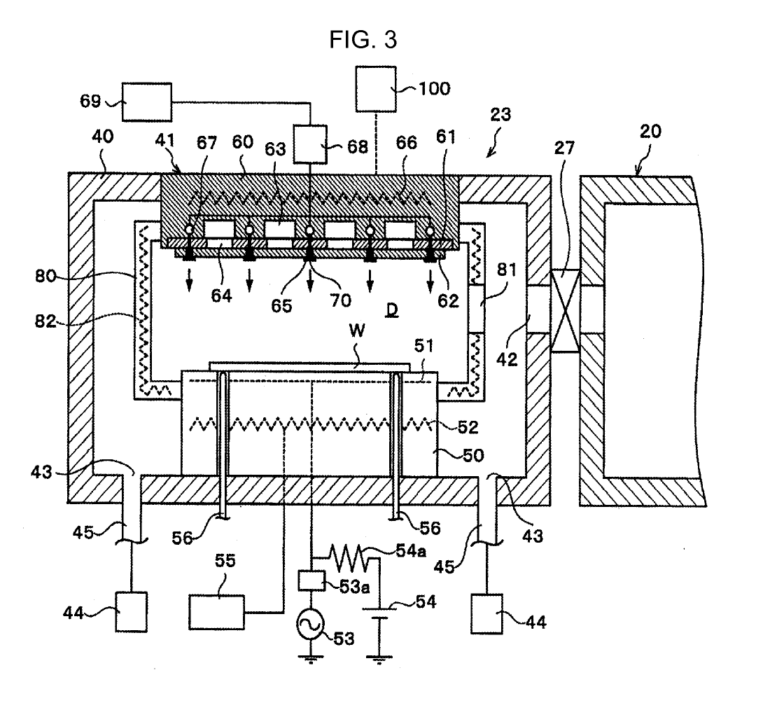

As shown in FIG. 3, the processing apparatus 23 includes a processing chamber 40 of which a portion of a top surface is opened, and a lid 41 as a processing mechanism disposed on the top surface opening of the processing chamber 40. The processing chamber 40 and the lid 41 may be formed of an aluminum alloy, and are both grounded.

An opening 42 for carrying the substrates W in and out of the processing chamber 40 is formed on a side of the processing chamber 40, at a location corresponding to the gate valve 27. Also, an exhaust opening 43 for exhausting an atmosphere inside the processing chamber 40 is formed on a bottom portion of the processing chamber 40. The exhaust opening 43 is connected to an exhaust pipe 45 leading to an exhauster 44, such as a vacuum pump. According to exhaust from the exhaust opening 43, the inner space of the processing chamber 40 may be depressurized down to a predetermined pressure.

A loading stage 50 for loading the substrates W on is disposed inside the processing chamber 40. The loading stage 50 may be formed of an aluminum nitride. An electrode plate 51 for electrostatically-adsorbing the substrate W while applying a predetermined bias voltage to the inner space of the processing chamber 40, and a heater 52 for heating the substrate W to a predetermined temperature are disposed inside the loading stage 50. The electrode plate 51 is connected to a high frequency power source 53 for bias applying, which is disposed outside the processing chamber 40, through a matcher 53a including a condenser and the like, and also connected to a high voltage direct current (DC) power source 54 for electrostatic absorption through a coil 54a. The heater 52 is connected to an alternating current (AC) power source 55 that is also disposed outside the processing chamber 40.

An elevation pin 56 for elevating/lowering the substrate W by holding the substrate W from below is formed in the loading stage 50. The elevation pin 56 may move up and down by an elevation driving mechanism (not shown) by penetrating the loading stage 50 in a thickness direction thereof. Also, the elevation pin 56 elevates to a transfer location above the loading stage 50 when transferring the substrates W, and is hidden in the loading stage 50 at other times.

The lid 41 disposed on the top surface opening of the processing chamber 40 faces the upper portion of the loading stage 50. The lid 41 is formed by, for example, adhering a slot antenna 61 to a bottom surface of a lid body 60 formed of aluminum, and additionally adhering a plurality of dielectrics 62 that will be described later to a bottom surface of the slot antenna 61. Here, the lid body 60 and the slot antenna 61 are integrally formed as one body. Also, the slot antenna 61 may be formed of aluminum, and each dielectric 62 may be formed of quartz glass, aluminum nitride (AlN), aluminum oxide (Al₂O₃), sapphire, silicon nitride (SiN), ceramics, or the like.

A plurality of waveguides 63 are disposed on the bottom surface of the lid body 60. Each waveguide 63 is connected to a microwave supplying apparatus (not shown) disposed outside the processing chamber 40. Also, microwaves having a frequency of, for example, 2.45 GHz, generated by the microwave supplying apparatus is introduced to each waveguide 63. Also, a plurality of slots 64 are disposed in the slot antenna 61 as holes for penetrating the microwaves. The slots 64 are formed at regular intervals along the waveguides 63, and are uniformly distributed on the entire bottom surface of the lid body 60. Also, an inner space of each waveguide 63 is filled with, for example Al₂O₃, quartz, or a fluorine resin.

The plurality of dielectrics 62 adhered to the slot antenna 61 are each formed in the slots 64 respectively, and thus are uniformly distributed on the entire bottom surface of the lid body 60. Each dielectric 62 is held by a holding member 65 having a lattice shape.

A heater 66 is disposed inside the lid body 60. The heater 66 is connected to an AC power source (not shown) disposed outside the processing chamber 40. The lid 41 is heated to a predetermined temperature by the heater 66.

Also, a gas passage 67 through which a predetermined gas flows is disposed inside the lid body 60. The gas passage 67 is connected to a gas supply source 69 through a mass flow controller 68 disposed outside the processing chamber 40. The gas supply source 69 contains an argon (Ar) gas as a plasma generating gas, or a SiH₄ gas or a H₂ gas as a processing gas. The gas passage 67 is disposed along the holding members 65 of the dielectrics 62, and is connected to each of a plurality of gas jets 70 respectively formed on the holding members 65. The gas jets 70 are formed at uniform intervals on the entire bottom surface of the lid body 60. Also, a predetermined gas supplied from the gas supply source 69 is ejected inside the processing chamber 40 from the gas jets 70.

An internal chamber 80 for forming a processing space D is disposed between the lid 41 and the loading stage 50. The internal chamber 80 is formed to cover the circumferences of the lid 41 and the loading stage 50. An opening 81 for carrying the substrates W into and out of the internal chamber 80 is formed in a sidewall of the internal chamber 80 at a location facing the opening 42 of the processing chamber 40. A heater 82 for maintaining the processing space D at a predetermined temperature is disposed inside the internal chamber 80. The heater 82 is connected to an AC power source (not shown) disposed outside the processing chamber 40.

The processing of the substrates W in the processing apparatus 23 is controlled by the controller 100 that will be described later.

Also, the structures of the processing apparatuses 24 through 26 are identical to the structure of the processing apparatus 23 described above, and thus descriptions thereof are not repeated herein.

The controller 100 for controlling the transferring of the substrates W by using the transfer apparatus 32 or the processing of the substrates W by using the processing apparatuses 23 through 26 will now be described. The controller 100 may include a general-purpose computer including a central processing unit (CPU) or a memory.

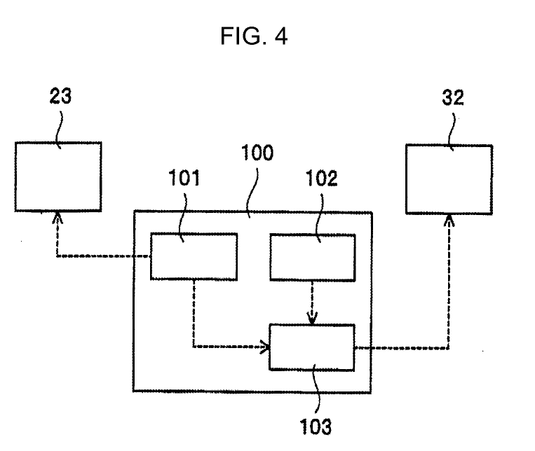

As shown in FIG. 4, the controller 100 includes a recipe setter 101 that sets a processing recipe for performing a predetermined process on the substrates W by using the processing apparatus 23.

The recipe setter 101 sets the processing recipe according to the input of an operator. Examples of parameters of the processing recipe include a type or flow rate of a gas supplied from the gas supply source 69 into the processing chamber 40, a processing time of the substrates W in the processing chamber 40, a voltage applied to the processing chamber 40 by the electrode plate 51, a pressure inside the processing chamber 40, and a setting temperature of each of the heaters 52, 66, and 82. Then, the processing recipe is output from the recipe setter 101 to the processing apparatus 23, and thus a predetermined process is performed on the substrates W based on the processing recipe. At the same time, the processing recipe is output from the recipe setter 101 to a compensator 103.

The controller 100 further includes a memory 102 for storing various types of information for compensating a reference location of the transfer arm 33 of the transfer apparatus 32, and the compensator 103 for compensating the reference location of the transfer arm 33.

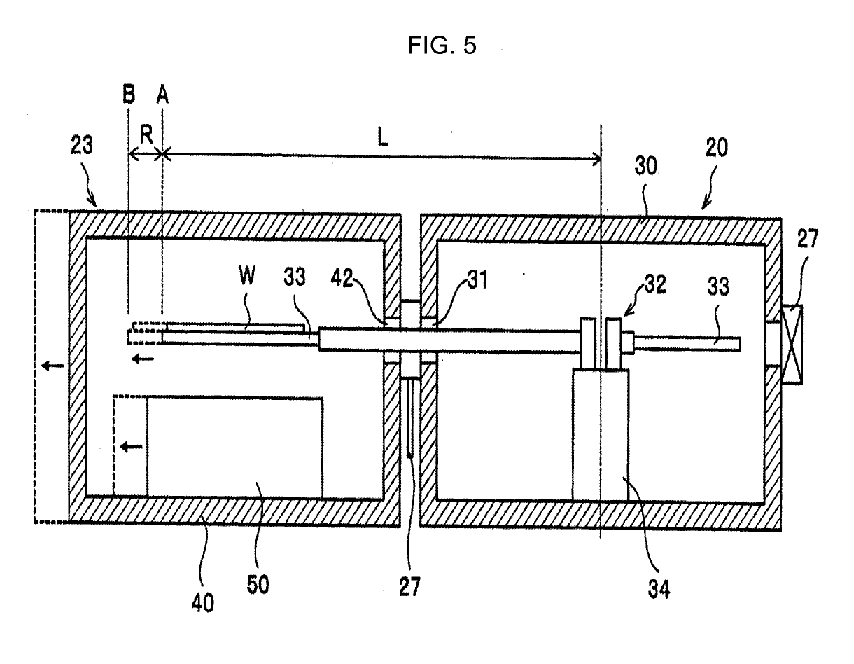

Here, the reference location of the transfer arm 33 is a location of the transfer arm 33 that is set in such a way that a substrate W is disposed at a predetermined location with respect to the loading stage 50, and according to the present embodiment, is a location where the transfer arm 33 delivers the substrate W with respect to the loading stage 50 as shown in FIG. 5. The reference location is set based on a distance of a length direction of the transfer arm 33, i.e. a distance from the center of the arm holding member 34 to the front end of the transfer arm 33. Also, the controller 100 controls the transferring of the substrate W by controlling the reference location of the transfer arm 33 by controlling the transfer apparatus 32.

When the substrate W is processed, the inner space of the processing chamber 40 is heated to a high temperature, and thus the processing chamber 40 outwardly expands (dotted line of FIG. 5) due to thermal expansion, compared to before the processing of the substrate W (solid line of FIG. 5, during teaching that will be described later). At this time, the location of the loading stage 50 also deviates outwardly, and thus the location of the substrate W deviates with respect to the loading stage 50. The controller 100 also compensates the reference location of the transfer 33 in order to remove a deviation of the substrate W with respect to the loading stage 50.

In order to control the reference location of the transfer arm 33 described above, the memory 102 stores an initial reference location A, which is an initial setting of the reference location of the transfer arm 33, and a relationship between the processing recipe and a compensated value R of the reference location while processing the substrate W. Here, the compensated value R of the reference location is a compensated value from the initial reference location A, and may be in a range of 0.2 mm to 0.3 mm.

The initial reference location A stored in the memory 102 is predetermined according to an operation known as teaching that is performed before processing the substrate W, under an atmosphere of normal temperature, for example, between 20° C. and 40° C. Also, in FIG. 5, L denotes a distance from the center of the arm holding member 34 to the front end of the transfer arm 33 in the initial reference location A.

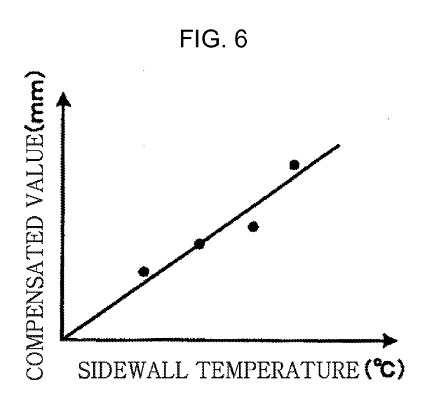

The relationship stored in the memory 102 includes a first correlation between the processing recipe and a sidewall temperature of the processing chamber 40, and a second correlation between the sidewall temperature of the processing chamber 40 and the compensated value R of the reference location. The first correlation is obtained by processing the substrate W based on various types of processing recipes, and measuring the sidewall temperature of the processing chamber 40 corresponding to each processing recipe. Also, the second correlation may be obtained by measuring the compensated value R of the reference location regarding the sidewall temperature of the processing chamber 40 through pre-experiment. For example, as shown in FIG. 6, the second correlation may be obtained by plotting the sidewall temperature of the processing chamber 40 and the compensated value R of the reference location on a graph, and by linear-complementing the plot line.

A plurality of the initial reference locations A, a plurality of the first correlations, and a plurality of the second correlations may be stored in the memory 102 according to a characteristic of the processing chamber 40. The characteristic of the processing chamber 40 may be, for example, a material, a structure, or a size of the processing chamber 40. The initial reference location A, the first correlation, and the second correlation are output to the compensator 130 from the memory 102. The parameters of the processing recipe include various types as described above, but the parameter used for the first correlation may be limited to a parameter having a high correlation with the sidewall temperature of the processing chamber 40. In the present embodiment, the first correlation is applied to each of the heaters 52, 66, and 82.

The compensator 103 contains a program for compensating the reference location of the transfer arm 33 while processing the substrate W. The program calculates a suitable reference location B by calculating the compensated value R of the reference location of the transfer arm 33 shown in FIG. 5, based on the processing recipe set in the recipe setter 101, and the initial reference location A, the first correlation, and the second correlation stored in the memory 102. In other words, the reference location B is a location where a distance from the center of the arm holding member 34 to the front end of the transfer arm 33 is “L+R”. Also, the compensated reference location B is output from the compensator 103 to the transfer apparatus 32, thereby compensating the reference location of the transfer arm 33.

The program contained in the compensator 103 is recorded on a computer readable recording medium, such as a computer readable hard disk (HD), a flexible disk (FD), a compact disc (CD), a magnet optical disk (MO), or a memory card, and may be installed in the controller 100 from the recording medium.

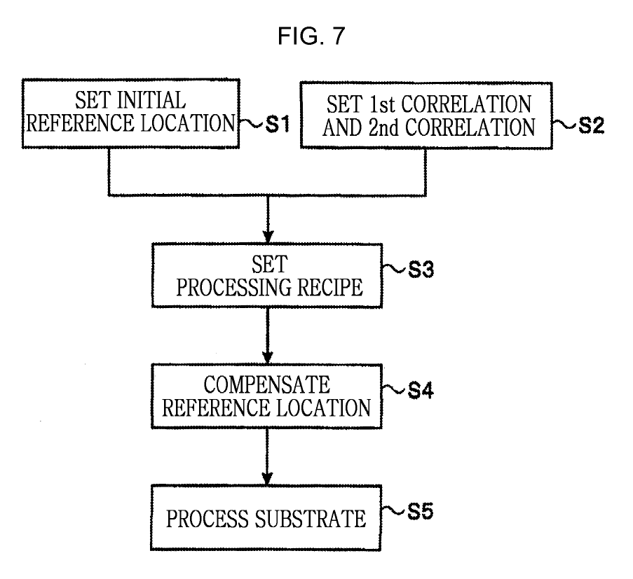

Processing processes performed in the substrate processing system 1 described above will now be described. FIG. 7 is a flowchart illustrating important operations of the processing processes.

First, before processing the substrates W, teaching is performed under an atmosphere of normal temperature. In detail, the gate valve 27 is opened and the transfer arm 33 holding the substrate W enters the processing chamber 40 thereby carrying the substrate W into the processing chamber 40. Also, in order for the transfer arm 33 to deliver the substrate W to an accurate predetermined location on the loading stage 50, an operator adjusts the transfer arm 33 on an accurate location for delivery. The location of the transfer arm 33 is set to the initial reference location A, and is stored in the memory 102, in operation S1 of FIG. 7.

Also, before processing the substrates W, experiments are performed on the processing chamber 40 so as to obtain the first correlation and the second correlation described above, and the first and second correlations are stored in the memory 102, in operation S2 of FIG. 7.

Then, in operation S3 of FIG. 7, the processing recipe for processing the substrates W is input and set in the recipe setter 101.

The initial reference location A, the first correlation, the second correlation, and the processing recipe are output to the compensator 103. The compensator 103 calculates the suitable reference location B by calculating the compensated value R of the reference location of the transfer arm 33 based on the initial reference location A, the first correlation, the second correlation, and the processing recipe. Then, the compensated reference location B is output from the memory 102 to the transfer apparatus 32, thereby compensating the reference location of the transfer arm 33, in operation S4 of FIG. 7.

Next, the substrates W are processed based on the processing recipe set in the recipe setter 101. While processing the substrates W, first, the substrates W are extracted one by one from the cassette C of the cassette station 2 by the substrate transfer unit 14, and are transferred to the alignment unit 12. The location of the substrate W is adjusted to the location of the alignment unit 12, and then is transferred to the load lock chamber 21 by the substrate transfer unit 14.

Next, the substrate transfer unit 14 is withdrawn, and the gate valve 27 disposed outside the load lock chamber 21 is closed. Then, the inner space of the load lock chamber 21 is exhausted, so as to depressurize the inner space down to a predetermined pressure.

Then, the gate valve 27 between the main transfer chamber 20 and the load lock chamber 21 is opened, and the substrate W in the load lock chamber 21 is received by the transfer apparatus 32 in the main transfer chamber 20.

When the substrate W is transferred into the main transfer chamber 20, the gate valve 27 between the main transfer chamber 20 and the load lock chamber 21 is closed while the gate valve 27 between the main transfer chamber 20 and the processing apparatus 23 is opened. Here, the inner space of the main transfer chamber 20 is maintained in a vacuum state, and thus the substrate W passing within the main transfer chamber 20 is vacuum-transferred.

Then, the substrate W is carried into the processing chamber 40 from the main transfer chamber 20 through the openings 31 and 42, by the transfer apparatus 32. Here, the transfer arm 33 expands to the reference location B compensated in operation S4, and the substrate W held by the transfer arm 33 is transferred to a predetermined location with respect to the loading stage 50. Then, the elevation pin 56 is elevated, thereby delivering the substrate W on the elevation pin 56 from the transfer arm 33. Next, the transfer arm 33 in the processing chamber 40 is withdrawn to the main transfer chamber 20, and then the elevation pin 56 is lowered so as to place the substrate W on the loading stage 50. Also, when the substrate W is carried into the processing chamber 40 as such, each of the heaters 52, 66, and 82 in the processing chamber 40 is adjusted to a temperature set in the processing recipe, for example, between 100° C. and 200° C.

Next, the gate valve 27 is closed, and the inner space of the processing chamber 40 is depressurized down to a pressure set in the processing recipe by using the exhauster 44. Then, a predetermined gas, such as a mixed gas of argon, silane, and hydrogen, set in the processing recipe is supplied from the gas supply source 69 to the processing space D in the processing chamber 40 through the gas passage 67 and the gas jets 70 at a predetermined flow rate. In this case, the predetermined gas may be uniformly supplied to the entire surface of the substrate W loaded on the loading stage 50 by ejecting the predetermined gas from the gas jets 70 distributed on the entire bottom surface of the lid body 60.

Also, while supplying the predetermined gas into the processing chamber 40 from the gas supply source 69, the microwaves, having a frequency such as 2.45 GHz, generated by the microwave supplying apparatus is propagated to each dielectric 62 through each of the slots 64 from each waveguide 63. Accordingly, an electromagnetic field is formed in the processing space D in the processing chamber 40 according to energy of the microwaves propagated in each dielectric 62, and the predetermined gas supplied to the processing chamber 40 becomes plasma. Such a plasma process is performed for a predetermined time set in the processing recipe. Also, during the plasma process, a voltage set in the processing recipe is applied to the processing chamber 40 by the electrode plate 51 of the loading stage 50.

When the plasma process is completed, the inner space of the processing chamber 40 is purged, and the gate valve 27 is opened. Then, while holding the substrate W, the elevation pin 56 is elevated to a predetermined height while the transfer arm 33 is entered into the processing chamber 40. Here, the transfer arm 33 expands to the reference location B described above. Then, the substrate W is delivered from the elevation pin 56 to the transfer arm 33, and the transfer arm 33 is withdrawn from the processing chamber 40.

The substrate W is delivered to the substrate transfer unit 14 through the load lock chamber 22 from the main transfer chamber 20, and returned back to the cassette C. As such, a series of processes is completed in operation S5 of FIG. 7.

Also, when the processing recipe is updated in the recipe setter 101, in operation S3 of FIG. 7 in order to perform another process on the substrate W, the reference location B compensated in the compensator 103 is also automatically updated in operation S4 of FIG. 7.

According to the above embodiment, since the memory 102 stores the initial reference location A, the first correlation, and the second correlation, when the recipe setter 101 sets the processing recipe, the compensator 103 may immediately and automatically compensate the reference location of the transfer arm 33 while processing the substrate W. In other words, the location of the transfer arm 33 may be automatically and immediately compensated in such a way that the substrate W is disposed at a predetermined location with respect to the loading stage 50. Accordingly, even when the processing chamber 40 thermally expands as the temperature inside the processing chamber 40 increases, the transfer arm 33 is moved based on the reference location B compensated by the compensator 103, and thus the substrate W may be highly precisely and quickly transferred to the predetermined location with respect to the loading stage 50 by using the transfer arm 33. In this case, the reference location is not required to be manually compensated unlike a conventional technology, and thus the reference location may be accurately compensated. Moreover, since a temperature sensor for detecting a temperature of a processing chamber is not required unlike a conventional technology, the structure of the substrate processing system 1 may be simplified.

Also, when the processing recipe is updated in the recipe setter 101, the reference location B compensated in the compensator 103 is also automatically updated, and thus the reference location of the transfer arm 33 may be more accurately compensated.

Also, it may be considered that it is enough to store only a correlation between the processing recipe and the compensated value of the reference location in the memory 102. However, for example, when things matched with the set processing recipe are not stored in the memory 102, the compensated value of the reference location cannot be calculated only by using the correlation between the processing recipe and the compensated value of the reference location. Meanwhile, since the memory 102 stores the first correlation and a second correlation, even with the processing recipe described above, the sidewall temperature of the processing chamber 40 may be calculated from the first correlation, and the compensated value of the reference location may be calculated from the second correlation. In other words, the present embodiment may deal with various types of processing recipes.

Also, when the processing recipes are the same but the characteristics of the processing chamber 40 are different, the processing chamber 40 may expand differently due to the thermal expansion while processing the substrate W. Here, according to the present embodiment, the memory 102 stores the plurality of initial reference locations A, the first correlations, and the second correlations according to the characteristic of the processing chamber 40, and thus the reference location of the transfer arm 33 may be compensated according to the characteristics of the processing chamber 40. In other words, the present embodiment may deal with various types of processing chambers.

The above embodiments do not consider excessive thermal expansion of the processing chamber 40, but excessive thermal expansion may be considered according to another embodiment. In other words, since a predetermined time is required until thermal expansion of the processing chamber 40 is stabilized, when the substrate W is processed in the processing chamber 40 for the first time after the temperature of the processing chamber 40 deceases near to room temperature due to maintenance or the like, the sidewall temperature of the processing chamber 40 may not be in a stable status and the processing chamber 40 may be in the middle of thermally expanding. Considering such a possibility, a time after the processing chamber 40 starts may be measured, and when the time is less than a certain time, for example 30 minutes, required until the thermal expansion of the processing chamber 40 stabilizes, the sidewall temperature obtained from the first correlation may be compensated to decrease. As such, the compensated value R having a higher precision may be obtained.

Also in the above embodiments, the reference location of the transfer arm 33 is set based on a length of the transfer arm 33 in the length direction thereof, but may also be set based on a length of the transfer arm 33 in a horizontal direction crossing the length direction at right angles, or a height of the transfer arm 33. For example, even if the change of the distances is within a permitted range even when the processing chamber 40 thermally expands while processing the substrate W, the distances may be compensated in order to more accurately compensate the reference location.

The present invention is useful when a predetermined process is performed on a substrate by using a predetermined recipe, and specifically, is useful when the substrate is highly precisely transferred to a predetermined location with respect to a loading stage in a processing chamber.

According to the present invention, a structure of a substrate processing system can be simplified, and a substrate can be highly precisely and quickly transferred to a predetermined location with respect to a loading stage in a processing chamber.

While this invention has been particularly shown and described with reference to exemplary embodiments thereof, it will be understood by those skilled in the art that various changes in form and details may be made therein without departing from the spirit and scope of the invention as defined by the appended claims. The present invention is not limited to the embodiments, but may employ various types of shapes. The present invention may be applied even when a substrate is a mask reticle for a flat panel display (FPD) or a photomask, aside from a wafer. Also, a process performed in a processing apparatus may be a plasma process, such as an etching process, aside from a CVD process, and may be a heat-accompanying process, aside from the plasma process. Also, the shape of a transfer arm is not limited to the embodiments described above, and the present invention may use various types of transfer arm.

What is claimed is:

1. A substrate processing system comprising:
a processing chamber for accommodating a loading stage for accommodating a substrate and comprising an opening for carrying the substrate into and out of the processing chamber;
a processing mechanism for performing a predetermined process on a substrate disposed on the loading stage, based on a predetermined processing recipe;
a transfer arm for transferring the substrate with respect to the loading stage through the opening; and
a controller for controlling the transfer of the substrate by the transfer arm,
wherein the controller comprises:
a memory for storing an initial reference location predetermined before processing the substrate as a reference location of the transfer arm that is set in such a way that the substrate is disposed at a predetermined location with respect to the loading stage, and a relationship between the processing recipe and a compensated value of the reference location when the substrate is processed; and
a compensator for compensating the reference location when the substrate is processed, based on the processing recipe, the initial reference location, and the relationship.

2. The substrate processing system of claim 1, wherein the controller further comprises a recipe setter for controlling the process of the substrate by the processing mechanism and setting the processing recipe, wherein, when the processing recipe is updated in the recipe setter, the compensated reference location in the compensator is updated.

3. The substrate processing system of claim 1, wherein the relationship comprises a first correlation between the processing recipe and a sidewall temperature of the processing chamber, and a second correlation between the sidewall temperature of the processing chamber and the compensated value of the reference location.

4. The substrate processing system of claim 3, wherein a plurality of each of the initial reference location, the first correlation, and the second correlation are stored in the memory according to a characteristic of the processing chamber.

5. The substrate processing system of claim 1, wherein the initial reference location is set under an atmosphere of normal temperature.

6. The substrate processing system of claim 1, wherein the reference location is set based on a distance of a length direction of the transfer arm.

7. The substrate processing system of claim 1, wherein the reference location is a location where the transfer arm delivers the substrate with respect to the loading stage.

8. A substrate transfer method in which a substrate is transferred by a transfer arm with respect to a loading stage in a processing chamber where a predetermined process is performed on the substrate based on a predetermined processing recipe, the substrate transfer method comprising:
setting an initial reference location before processing the substrate, as a reference location of the transfer arm that is set in such a way that the substrate is disposed at a predetermined location with respect to the loading stage;
obtaining a relationship between the processing recipe and a compensated value of the reference location when the substrate is processed;
compensating the reference location when the substrate is processed, based on the processing recipe, the initial reference location, and the relationship; and
transferring the substrate with respect to the loading stage by the transfer arm, based on the compensated reference location.

9. The substrate transfer method of claim 8, wherein the compensating of the reference location is performed whenever the processing recipe is updated.

10. The substrate transfer method of claim 8, wherein the relationship comprises a first correlation between the processing recipe and a sidewall temperature of the processing chamber, and a second correlation between the sidewall temperature of the processing chamber and the compensated value of the reference location, and
the compensating of the reference location is performed based on the processing recipe, the initial reference location, the first correlation, and the second correlation.

11. The substrate transfer method of claim 10, wherein a plurality of each of the initial reference location, the first correlation, and the second correlation are obtained according to a characteristic of the processing chamber.

12. The substrate transfer method of claim 8, wherein the setting of the initial reference location is performed under an atmosphere of normal temperature.

13. The substrate transfer method of claim 8, wherein the reference location is set based on a distance of a length direction of the transfer arm.

14. The substrate transfer method of claim 8, wherein the reference location is a location where the transfer arm delivers the substrate with respect to the loading stage.
